(19) United States
(12) Patent Application Publication
(10) Pub. No.: US 2025/0149390 A1
(43) Pub. Date: May 8, 2025

(54) WAFER PROCESS FOR PROBING BUMP PLACEMENT ON MULTIPLE SMALL POWER PADS WITHOUT DISPLACING SURROUNDING SIGNAL PADS

(71) Applicant: XILINX, INC., San Jose, CA (US)

(72) Inventors: Andy WIDJAJA, Singapore (SG); Lik Huay LIM, Singapore (SG); Henley LIU, San Jose, CA (US); Jane Wang SOWARDS, Fremont, CA (US); Mohsen H. MARDI, Saratoga, CA (US)

(21) Appl. No.: 18/941,912

(22) Filed: Nov. 8, 2024

Related U.S. Application Data
(60) Provisional application No. 63/597,256, filed on Nov. 8, 2023.

(51) Int. Cl. H01L 21/66; H01L 23/00; H01L 25/065

(52) U.S. Cl. CPC H01L 22/32; H01L 22/12; H01L 24/03; H01L 24/08; H01L 25/0657; H01L 2224/0392; H01L 2224/08145; H01L 2225/06565

(57) ABSTRACT

Methods for fabricating an integrated circuit (IC) device, an IC die configured for probe testing, and an IC device are described therein. In one example, the method includes: forming a conductive cap above and in electrical contact with two or more of a pillars, each pillar coupled to a power contact pads of an IC die, removing the cap after testing; and depositing a hybrid bonding layer over the IC die device, the hybrid bonding layer having hybrid bond pads coupled the plurality of power contact pads and the signal contact pads of the IC die.

### CROSS REFERENCE TO RELATED APPLICATION

This application claims priority to the U.S. Provisional Patent Application Ser. No. 63/597,256 filed Nov. 8, 2023 of which is incorporated herein by reference in its entirety.

### TECHNICAL FIELD

Embodiments of the present disclosure generally relate to integrated circuit (IC) dies and devices, and techniques for manufacturing the same. In particular, to an IC die that utilizes ganged power pads contacted by a single probe pin during the IC die fabrication process.

### BACKGROUND

Electronic devices, such as tablets, computers, server, in-door telecom, out-door telecom, industrial computers, high performance computing data centers, copiers, digital cameras, smart phones, control systems and automated teller machines, among others, often employ electronic components which leverage chip package assemblies for increased functionality and higher component density. Conventional chip package assemblies include one or more stacked components such as integrated circuit (IC) dies, through-silicon-via (TSV) interposer, and a package substrate, with the chip package itself stacked on a printed circuit board (PCB). The IC dies may include memory, logic, MEMS, RF or other IC device.

With progressive decreases in technologies nodes, conventional IC die stacking and contact pad spacing has presented new challenges. For example, moving to N2 technology node requires the use of hybrid bonds for Active-On-Active (AoA) die stacking. AoA stacking requires the use of many signal transfers between upper die to lower die. This results in many signal pads to be placed around power pads. Die-to-die signals do not require probing, but power pads require probing at wafer sort. Large metal (either aluminum or copper) pads are used as base for placement of probing bumps in existing wafers fabricated in the N7 technology node where there is still enough room for these large pads. However, in smaller technology nodes, these large pads take up too much space and will consume the space needed for many signal pads. Thus, traditional large power pads will displace many signal pads is used in smaller technology nodes.

Thus, there is a need for an improved IC die and methods for fabricating the same.

### SUMMARY

Methods for fabricating an integrated circuit (IC) device, an IC die configured for probe testing, and an IC device are described therein. In one example, the method includes: depositing a passivation layer over a surface of a IC die having a plurality of signal and power contact pads, the passivation layer masking the signal contact pads while having openings exposing the power contact pads; filing the openings with a conductive material to form a plurality of conductive pillars in electrical contact with the power contact pads; forming a conductive cap above and in electrical contact with two or more of the pillars; probing the power contact pads through the conductive cap; removing the passivation layer and the conductive cap; and depositing hybrid bonding layer over the surface of the IC die device, the hybrid bonding layer having hybrid bond pads coupled the plurality of power contact pads and the signal contact pads of the IC die.

In another example, an integrated circuit (IC) die is provided. The IC die includes a die body having functional circuitry formed therein. A plurality of signal terminations are disposed on a buried surface of the die body. The plurality of signal terminations are coupled to the functional circuitry. A plurality of power terminations are also disposed on the buried surface of the die body and coupled to the functional circuitry. A passivation layer is disposed on the buried surface of the die body. The plurality of signal terminations electrically dead ended below the passivation layer. A plurality of probe contact pads are disposed on an exposed surface of the passivation layer. The probe contact pads are electrically coupled to the plurality of power terminations. A conductive cap is disposed exposed surface of the passivation layer. The conductive cap in contact with at least two of the plurality of probe contact pads.

In yet another example, an integrated circuit (IC) device is provided. The IC device includes a first and second IC dies. The first IC die includes a polished surface having a plurality of signal contact pads and power contact pads. The polished surface having a passivation layer and a hybrid bonding layer formed thereon. The second IC die includes a polished surface also having a plurality of signal contact pads and power contact pads. The polished surface of the second IC die has a passivation layer and a hybrid bonding layer formed thereon. The hybrid bonding layer of the first IC die is hybrid bonded to the hybrid bonding layer of the second IC die.

### BRIEF DESCRIPTION OF DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is top isometric schematic view a portion of a wafer illustrating one of a plurality of integrated circuit (IC) dies formed thereon.

FIG. 2 is top isometric schematic view one of the plurality of IC dies of the wafer with a temporary passivation layer formed thereon. The other IC dies constituting the wafer are not illustrated in FIG. 2.

FIG. 3 is a cross sectional schematic view of a portion of the IC die having conductive caps coupled only to exposed power pads. In FIG. 3, the IC die is illustrated interfaced with an automatic testing device.

FIG. 4 is a partial top view of a portion of the IC die illustrating the conductive cap coupled only to the exposed power pads, while the signal pads remain masked by the temporary passivation layer.

FIG. 5 is top isometric schematic view a portion of the wafer illustrating an IC die after the temporary passivation layer has been removed.

FIG. 6 is top isometric schematic view a portion of the wafer illustrating an IC die having a hybrid bonding layer formed thereon.

FIG. 7 is a schematic side view a portion of a chip package having two IC dies joined by a hybrid bonding.

FIG. 8 is a flow diagram of a method for forming an IC die.

To facilitate understanding, identical reference numerals have been used, where possible, to designate identical elements that are common to the figures. It is contemplated that elements of one embodiment may be beneficially incorporated in other embodiments

### DETAILED DESCRIPTION

Methods for fabricating an integrated circuit (IC) device, an IC die configured for probe testing, and an IC device are described therein. Although the following description and drawings are detailed at the IC die level, it is to be understood that the method described herein may be practiced on an IC die before or after singulatation from an original or reconstituted wafer.

In one example, the method includes probing power pads on an integrated circuit (IC) die. The method includes depositing an initial passivation layer over all of the signal power pads, leaving only the power pads exposed. The exposed power pads can then be probed for IC die testing without undesirably contacting the signal pads since the signal pads are covered by the initial passivation layer. After probing, the initial passivation layer is removed and replaced by a final passivation layer that has opening leaving both the power, ground and signal pads exposed. A hybrid bonding layer can then be fabricated on the final passivation layer leaving the tested IC die ready for stacking with another IC die.

The novel process disclosed herein eliminates the need for big power pads while still enabling wafer sort probing. The process starts with the wafer top redistribution layer (RDL) with a column of power pads surrounded by signal pads. A passivation layer is placed on top with opening and metal connections only for the power pads. The passivation layer may be formed from one or more dielectric layers. The passivation layer may be fabricated from silicon nitride, polyimide or other suitable dielectric material. The signal pads are masked out by the passivation layer. A metal pillar is then formed through the passivation layer with connections only to the power pads within a column, as the signal pads remain masked by the passivation layer. The metal pillar may be formed from copper, aluminum or other suitable electrically conductive material. A conductive cap, also referred to as a probing bump, is disposed on two or more of the copper pillars and the top of the passivation layer for interfacing with the tip of a single test probe. The probing bump covers multiple power pads within the column of power pads. In one example, 6-12 or more power pads are covered (e.g., electrically connected in parallel) to a single conductive cap via the pillars. In other examples, power pads from two or more adjacent columns of power pads may be covered by a single conductive cap.

The wafer will then undergo wafer sort testing by probing on the probing bumps. After wafer sort, the probing bumps and passivation layer are removed by mechanical, chemical, chemical mechanical, and/or etching process to expose the top RDL. In one example, the probing bump is removed by lapping and/or chemical mechanical polishing. In one example, the passivation layer is removed by wet etching. Once the passivation layer has been removed, the top RDL has a polished surface that is much flatter than prior to deposition of the original passivation layer.

A new passivation layer is then placed on top of the wafer, but with opening exposing all the signal pads, ground pads, and power pads. The openings are filled with metal to create exposed contact pads. A hybrid bonding layer is then formed on the new passivation layer, with metal connections within the hybrid bonding layer to all the signal, ground, and power pads.

The wafer is then stacked active side to active side, with hybrid bonding layers providing the mechanical and electrical connections between the active on active (AoA) stacked wafers. Alternatively, the wafer may be stacked active side to passive side, with hybrid bonding layers providing the mechanical and electrical connections between the active and passive sides of the wafers.

This new technique eliminates the need for large power pads that are traditionally used for probing bumps used in wafer sort. For example, conventional power pads are about ten times the diameter of the power pads utilized in the present invention. Such large power pads would require the elimination of 2-10 columns of signal pads if used in 2N technology. As such the above described technique avoids displacement of signal pads that are required for hybrid bonds in N2 die stacking. This results in minimal or no disruption to the silicon design on the top RDL layer, and at the same time, allows for sufficient area to interface with conventional probes on probing bumps at wafer sort. After wafer sort, the probing bumps and top passivation layers are removed, allowing growth of hybrid bonds to facilitate AoA die stacking.

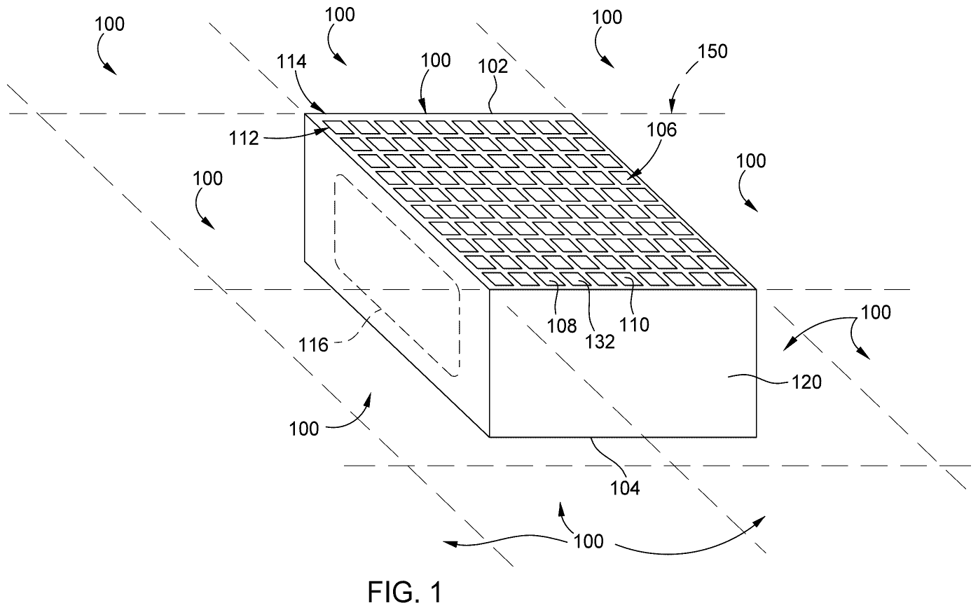

This new process starts at the wafer top RDL layer. In N2 silicon layout, the top RDL is populated with many rows and columns of small (i.e., less than 22 μm width/diameter, for example 5 μm) power, ground and signal pads. Power pads are usually arranged in one or more columns with many signal pad columns to the right and left sides. A single column of power pads are shown in FIG. 1. Passivation layers will be built on top of the RDL layer. A few masks layout will be needed to make opening on the passivation layers to provide metal connections to the power pads below. No opening made to the signal pads, so the signal pads will be masked out by the passivation.

Probing bump will then be grown on top of the passivation layer. Due to the passivation having metal opening and connections only to the power pads, the probing bump will only have connectivity to the power pads. The number of power pads connected can be 6 in a column or can be more (e.g., 12 pads if there are 2 columns of power pads). After bumping, the wafer will then go to wafer sort stage. At wafer sort, the wafer is tested using probe cards that have needles to probe on the probing bumps.

After wafer sort, the probing bump and passivation layer are removed by chemical mechanical polishing, lapping, grinding, milling and/or chemical etching process and/or other suitable process. This will expose the wafer top RDL layer again. The exposed top RDL layer will have a polished surface due to the passivation layer removal. A new passivation layers is applied on top the RDL layer but with openings and metal connections for all the power, ground and signal pads. Hybrid bonds are then grown on all the power, ground and signal pads. The wafer is then ready for die-stacking using hybrid bonds to attach die on die. The die on die stacking can be performed at a singulated die or wafer level (prior to singulatation) of the stacked die. The stacked dies are then used to form an electronic integrated circuit device.

The new process eliminates the need for large metal pads underneath the probing bumps. This allows for a single column of small power pads surrounded by many columns of signal pads, with minimal or no changes to the N2 top RDL layout at silicon design. So this will benefit silicon designers allowing them much flexibility in their placements of signal pads.

At the same time, with this new process probing bumps can still be grown on the wafer. Wafer sort testing will benefit from being able to probe on the bigger probing bumps. This allows the probe cards to use the existing proven probe technologies with higher current carrying capacity (CCC) for the needles.

Turning now to FIG. 1, a top isometric schematic view a portion of a wafer 150 illustrating one of a plurality of integrated circuit (IC) dies 100 formed thereon. The wafer 150 may be the original wafer on which the IC dies 100 were originally formed, or a reconstituted wafer made from a plurality of IC dies 100 rejoined together as a common substrate. Only one of the IC dies 100 is shown in detail in FIG. 1.

The IC die 100 includes a die body 120. The die body 120 has a top surface 102 and a bottom surface 104, which also are the top and bottom surfaces 102, 104 of the wafer 150. The top surface 102 may also include a redistribution layer (RDL) or other type of routing fan-out. The top surface 102 is also known as the active side of the IC die 100, with the bottom surface 104 comprised of the silicon substrate. Functional circuitry 116 is disposed in the die body 120. The functional circuitry 116 of the IC die 100 may include central processing unit (CPU) cores. As such, the IC die 100 containing CPU cores may be referred to as a CPU die or CPU chiplet. The functional circuitry 116 may also include System Management Unit (SMU). The SMU is circuitry configured to monitor thermal and power conditions and adjust power and cooling to keep the IC die 100 functioning as within specifications. The functional circuitry of the IC die 100 may also include Dynamic Function exchange (DFX) Controller IP circuitry. The DFX circuitry provides management of hardware or software trigger events. For example, the DFX circuitry may pull partial bitstreams from memory and delivers them to an internal configuration access port (ICAP). The DFX circuitry also assists with logical decoupling and startup events, customizable per Reconfigurable Partition. In the DFX circuitry, the “X” represents various purposes, such as DFD (Design for Debug), DFM (Manufacturability), DFR (Reliability), DFT (Test), and DFY (Yield), among others In another example, the functional circuitry 116 of the IC die 100 includes accelerated compute cores. As such, the IC die 100 containing accelerated compute cores may be referred to as an accelerator die or accelerator chiplet. The IC die 100 containing accelerated compute cores may also be referred to as a graphic processing unit (GPU) die or GPU chiplet. The accelerated compute cores contained in the functional circuitry 116 generally includes math engine circuitry. The math engine circuitry is generally designed for task specific computing, such as used data center computing, high performance computing and AI/ML computing. Along with the accelerated compute cores, functional circuitry 116 of the IC die may also include SMU circuitry and DFX circuitry, as mentioned above.

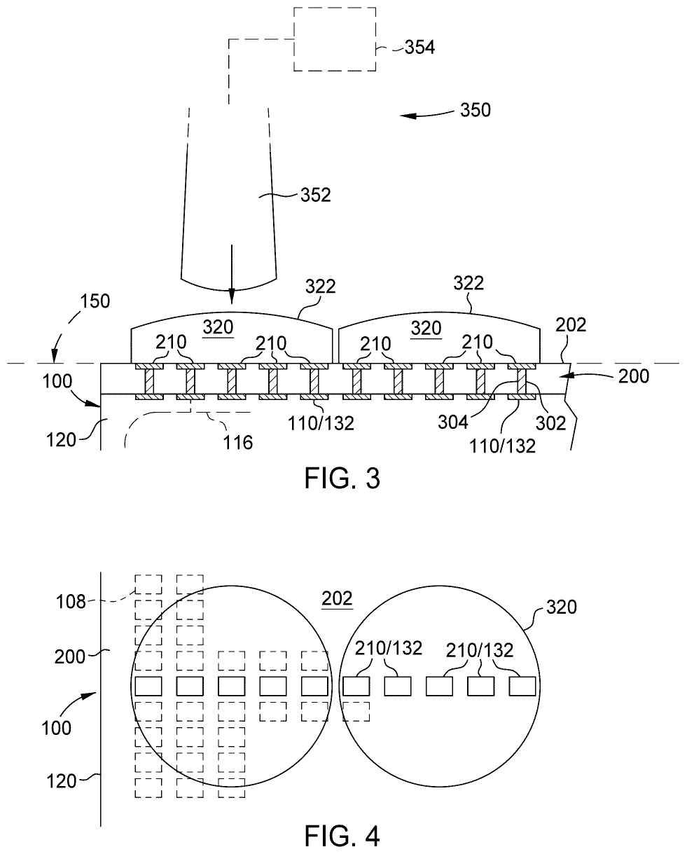

The functional circuitry 116 of the IC die 100 terminates at contact pads 106. The contact pads 106 are exposed on the top surface 102 of the IC die 100. The contact pads 106 are generally arranged in rows 112 and columns 114. In one example, spacing (e.g., pitch) between the contact pads 106 conforms to 2 nanometer technology as defined in the 2021 update of the International Roadmap for Devices and Systems published by the Institute of Electrical and Electronics Engineers. In some examples, the rows 112 and columns 114 of contact pads 106 are disposed in an X/Y grid pattern. In other examples, contact pads 106 in one row 112 and/or column 114 may be offset or staggered relative to the contact pads 106 of other rows 112 and/or columns 114. Stated differently, the arrangement of contact pads 106 on the top surface 102 may have any other desirable pattern or arrangement. Although the contact pads 106 are illustrated in FIGS. 3 and 4 as having a rectangular shape, the contact pads 106 may have a circular shape or any other desirable shape or pattern.

Collectively, the contact pads 106 includes ground pads 132, signal pads 108 and power pads 110. The ground pads 132 are configured to provide a ground for the functional circuitry 116. The signal pads 108 are configured to transmit signals to and from the functional circuitry 116. Although only one signal pad 108 is labeled in FIG. 1, the majority of the contact pads 106 are signal pads 108. The power pads 110 are configured to transmit power to the functional circuitry 116. Although only one power pad 110 is labeled in FIG. 1, the many of the contact pads 106 are power pads 110, albeit significantly less than the number of signal pads 108. In FIG. 1, at least some of the power pads 110 are arranged in a common column 114, as will become more evident below.

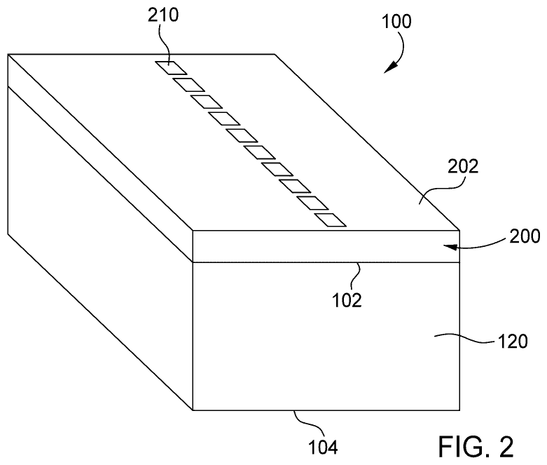

FIG. 2 is top isometric schematic view one of the plurality of IC dies 100 of the wafer 150 with a temporary passivation layer 200 formed thereon. The other IC dies 100 constituting the wafer 150 are not illustrated in FIG. 2.

The passivation layer 200 is formed on the top surface 102 of the IC die 100, and as such, the top surface of the wafer 150. The passivation layer 200 completely covers and thus buries the top surface 102. The passivation layer 200 also masks off, buries, and consequentially dead ends the signal pads 108 below the passivation layer 200 such that there is no electrical connection to the signal pads 108 through the passivation layer 200.

The passivation layer 200 may be fabricated from silicon nitride, polyimide or other suitable dielectric material. The passivation layer 200 has probing pads 210 arranged on an exposed surface 202 of the passivation layer 200 that faces away from the die body 120. Each probing pad 210 is coupled only to the t same type of contact pad 106. In one example, a single probing pad 210 may be coupled to two or more power pads 110. In another example, a single probing pad 210 may be coupled to two or more ground pads 132.

FIG. 3 is a cross sectional schematic view of a portion of the IC die 100 having probing pads 210 coupled only to the power pads 110 of the IC die 100. It is to be understood that the probing pads 210 may alternatively be coupled only to the ground pads 132 of the IC die 100. Additionally, some probing pads 210 may be coupled to two or more probing pads 210, while other probing pads 210 may be coupled to two or more ground pads 132. In FIG. 3, the IC die 100 is illustrated interfaced with an automatic testing device (ATD) 350. Although FIG. 3 only shows one IC die 100 interfaced with the automatic testing device 350, it is to be understood that the IC die 100 remains part of the wafer 150 while undergoing testing prior to singulatation.

In the example depicted in FIG. 3, the probing pads 210 are shown coupled to the power pads 110 via conductive pillars 304. The pillars 304 are formed in openings 302 formed in the passivation layer 200. The openings 302 may be formed in the passivation layer by any suitable technique, such as laser drilling, milling, etching and the like. The pillars 304 may be formed from copper, aluminum or other suitable electrically conductive material. The pillars 304 may be deposited in the opening 302 via plating or other suitable technique. In one example, the probing pad 210 may be the exposed end of the pillar 304, or a separate pad formed on the pillar 304. Probing pads 210 may optionally be coupled to the ground pads 132 in the same manner, Optionally, some of the pillars 304 are electrically floating to balance the distribution of metal across the wafer, thus enhancing warpage resistance and resulting in more robust and reliable electrical interconnections between the wafers.

A conductive cap 320 is disposed on and in electrical connection with at least two or more of the probing pads 210, and consequently, two or more of pillars 304 and their connected power pads 110 (or ground pads 132) of the IC die 100. The conductive cap 320 may be formed by solder, copper, aluminum or other suitable electrically conductive material. Although the conductive cap 320 is illustrated in FIGS. 3 and 4 as having a circular shape, the conductive cap 320 may have any other desirable shape or pattern. The conductive cap 320 includes a top surface 322 for interfacing with the tip of a test probe 352 of a probe card 354 of the ATD 350. A single conductive cap 320 covers multiple probing pads 210, and thus, is connected to multiple power pads 110 of the IC die 100. In the example depicted in FIG. 3, a single conductive cap 320 is connected to multiple power pads 110 within the column 114 of power pads 110. Although FIG. 3 depicts 5 probing pads 210 coupled to a single conductive cap 320, in other examples, 6 to 12 or more power pads 110 are covered (e.g., electrically connected in parallel) to a single conductive cap 320. In other examples, power pads 110 from two or more adjacent columns of power pads 110 may be are covered by a single conductive cap 320.

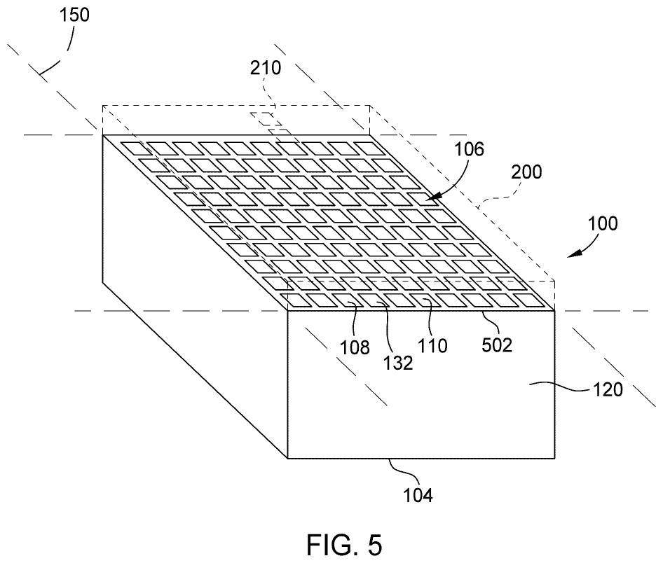

To more clearly illustrate that the conductive caps 320 coupled only to probing pads 210 that coupled only to the exposed power pads 110, while the signal pads 108 remain masked and buried below by the temporary passivation layer 200, the conductive caps 320 are shown disposed on the top surface 202 of the passivation layer 200 as illustrated in the partial top view of a portion of the IC die 100 of FIG. 4. After testing of the IC die 100 is completed by the ATE 350, the passivation layer 200, conductive cap 320, pillars 304 and probing pads 210 are removed from the IC die 100, leaving a newly exposed surface 502, as illustrated in FIG. 5. The newly exposed surface 502 may also include the RDL, if present on the original top surface 102. The passivation layer 200 may be removed by chemical mechanical polishing, lapping, grinding, milling and/or chemical etching process and/or other suitable technique. The newly exposed surface 502 of the IC die 100 is generally much smoother than the original top surface 102 of the IC die 100 due to the passivation layer removal process.

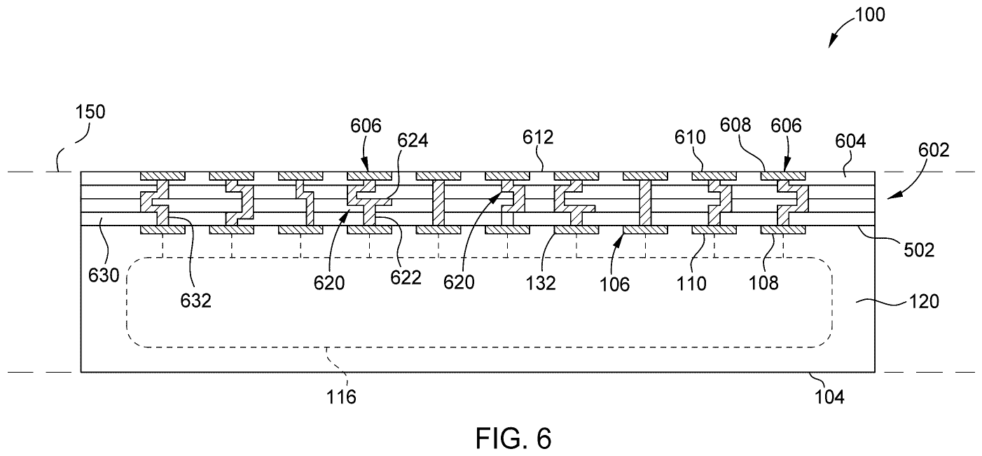

FIG. 6 is top isometric schematic view a portion of the wafer 150 illustrating an IC die 100 having a hybrid bonding layer 602 formed on the newly exposed surface 502 of the IC die 100 after the temporary (i.e., first) passivation layer 200 has been removed. The hybrid bonding layer 602 includes routing 620 formed through a plurality of dielectric layers 604. The dielectric layer 604 closest the die body 120 may be a passivation layer (i.e., second passivation layer) 630 formed from the same materials as described above. The passivation layer 630 may include an opening 632 through which the routing 620 is formed. At least the dielectric layer 604 farthest from the die body 120 is fabricated from oxides, thermal oxides, SiO₂, SiN, SiCN, polybenzoxazole (PBO), polyimide (PI), benzocyclobutene (BCB), among other materials that allow fusion bonding with a hybrid bonding layer of an adjacent IC die. The dielectric layer 604 includes an exposed top surface 612 that faces away from the die body 120.

The hybrid bonding pads 606 are exposed on the top surface 612 of the hybrid bonding layer 602. The hybrid bonding pads 606 are connected by the routing 620 to the contact pads 106 exposed on the new top surface 502 of the IC die 100. The routing 620 generally includes vias 622 and lines 624 formed between and/or in the dielectric layers 604. The routing 620 is generally formed form copper or other good electrical connector. Some of the hybrid bonding pads 606 are configured as ground pads and coupled to the contact pads 106 that are configured as ground pads 132. Some of the hybrid bonding pads 606 are configured as hybrid power pads 610 and coupled to the contact pads 106 that are configured as power pads 110. Some of the hybrid bonding pads 606 are configured as hybrid signal pads 608 and coupled to the contact pads 106 configured as signal pads 108. Optionally, some of the routing 602 is electrically floating to balance the distribution of metal across the wafer, thus enhancing warpage resistance and resulting in more robust and reliable electrical interconnections between the wafers.

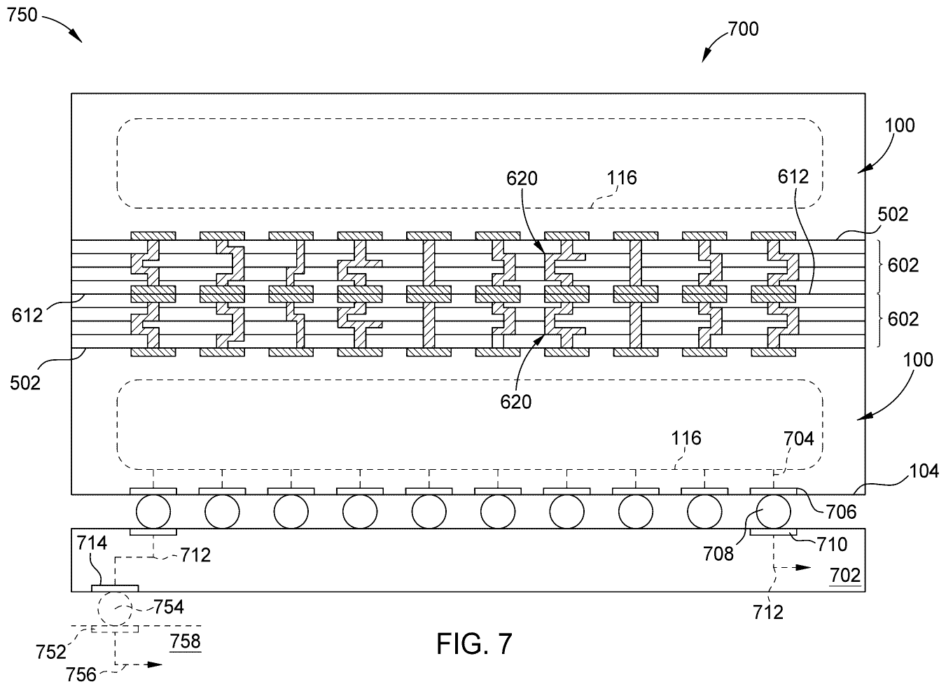

FIG. 7 is a schematic side view a chip package 700 having two IC dies 100 joined by hybrid bonding that are disposed on a package substrate 702. The IC dies 100 are fabricated as described above, with hybrid bonding layers 602 disposed on the active surfaces (e.g., top surfaces 502) of each IC die 100.

The IC dies 100 are hybrid bonded by forming non-metal to non-metal bonds using fusion bonding, and forming metal-to-metal bonds across the adjacent IC dies 100. The metal-to-metal bonds may be formed using pressure and heat to form eutectic metal bonds. In one example, a hybrid bond is formed by bonding the dielectric materials of the surface 612 surrounding the hybrid bond pads 606 on each IC die 100 to first secure the IC dies 100 together, followed by an interfusion of the metal materials of the hybrid bond pads 606 of the facing IC dies 100 to create the electric interconnect between the functional circuitry 116 of the one IC die 100 and the functional circuitry 116 of the vertically adjacent IC die 100.

The bottom IC die 100 is stacked on the package substrate 702. Although not shown in FIG. 7, there may be additional intervening IC dies and/or interposers disposed between the IC dies 100 shown in FIG. 7 and the package substrate 702. The bottom surface 104 of the IC die 100 closes the package substrate 702 includes bond pads 706. The bond pads 706 are coupled to the functional circuitry 116 of the IC die 100 by through silicon vias 704. The bond pads 706 are coupled by solder interconnects 708, such as solder bumps, to the bond pads 710 of the package substrate 702. The bond pads 710 of the package substrate 702 are connected by package circuitry 712 to bond pads 714 dispose on the opposite side of the package substrate 702.

The chip package 700 may be coupled with a printed circuit board 758 to form an electronic device 750. The chip package 700 may be coupled the printed circuit board 758 using a socket, or as shown in FIG. 7, solder balls 754. The solder balls 754 connects the bond pads 714 of the package substrate 702 with bond pads 752 of the printed circuit board 758, thus connecting the circuitry 756 of the printed circuit board 758 to the function circuitry 116 of the IC dies 100 of the chip package 700.

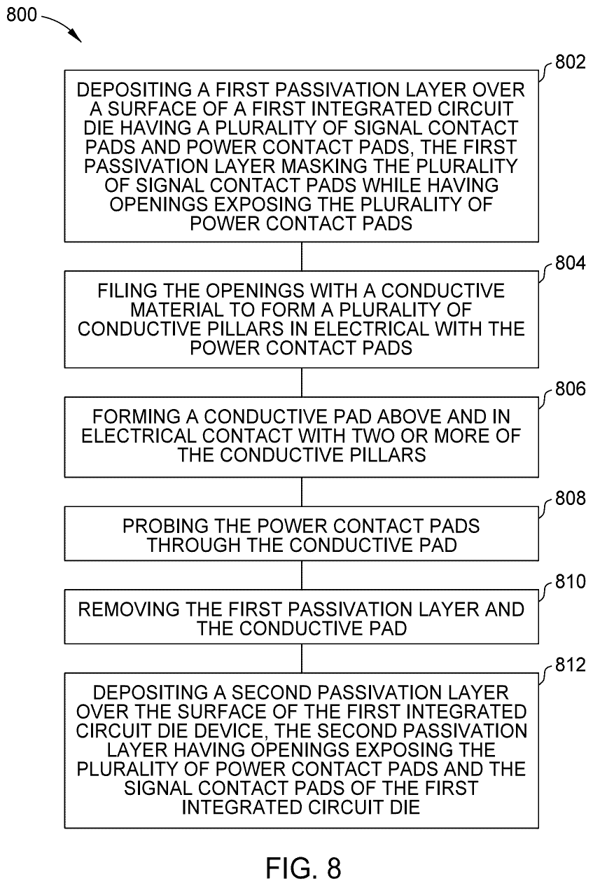

FIG. 8 is a flow diagram of a method 800 for forming an IC die, such as but not limited, to the IC die 100 described above. The method 800 begins at operation 802 by depositing a first passivation layer (i.e., passivation layer 200) over a surface of a first integrated circuit die 100 having a plurality of signal contact pads 108 and power contact pads 110, the first passivation layer masking the plurality of signal contact pads while having openings 302 exposing the plurality of power contact pads 110.

At operation 804, the openings 304 are filled with a conductive material to form a plurality of conductive pillars 304 that are in electrical contact with the power contact pads 110. The openings 304 may be filled by plating or other suitable technique to form the pillars 304. The portion of the pillars 304 exposed through the openings 304 in the passivation layer 200 form the probing pads 210. Optionally, the probing pad 210 may be separately formed on the portion of the pillars 304 exposed through the openings 304 in the passivation layer 200.

At operation 806, a conductive cap 320 is formed above and in electrical contact with two or more of the conductive pillars 304 through the probing pads 210. The conductive cap may be formed by depositing solder. The conductive cap may alternatively be formed by depositing a metal material on the pillar.

At operation 808, the power contact pads are probed through the conductive pillar to facility testing by an automatic testing device (ATD) 350. A single probe 352 of the ATD 350 applies power to multiple power contact pads 110 of the IC die 100 through contact of a single conductive cap 320. In the alterative or additionally, operations 802, 804, and 806 may be performed to connect some or all of the conductive caps 320 to the ground pads 132 such that the ground pads 132 may be probed at operation 808.

At operation 810, the first passivation layer 200, the conductive caps 320, and the conductive pillars 304 are removed. The first passivation layer 200, the conductive caps 320, and the conductive pillars 304 can be removed by chemical mechanical polishing, lapping, grinding, milling and/or chemical etching process and/or other suitable technique. The passivation layer removal operation 808 results a portion of the original top surface 102 of the IC die 100 being removed, leaving a new top surface 502 that is much smoother and polished relative to the original to surface 102.

At operation 812, a second passivation layer over the top surface 502 of the IC die 100. The second passivation layer having openings exposing the plurality of power contact pads 110 and the signal contact pads 108 of the IC die 100. In one example, the second passivation layer is part of a hybrid bonding layer 602 formed the top surface 502 of the IC die 100.

The IC die 100 having the hybrid bonding layer 602 is now ready for stacking and hybrid bonding with another IC die 100. The stacked IC dies 100 may be incorporated with a package substrate to form a chip package, such as the chip package 700. The chip package 700 may also be incorporated with a printed circuitry board to form an electronic device, such as the electronic device 750.

In addition to the examples described above, the disclosed technology may also be expressed in the following non-limiting examples.

Example 1. A method for fabricating an integrated circuit device, the method including: depositing a first passivation layer over a surface of a first integrated circuit die having a plurality of signal contact pads and power contact pads, the first passivation layer masking the plurality of signal contact pads while having openings exposing the plurality of power contact pads; filing the openings with a conductive material to form a plurality of conductive pillars in electrical contact with the power contact pads; forming a conductive cap above and in electrical contact with two or more of the conductive pillars; probing the power contact pads through the conductive pillar; removing the first passivation layer and the conductive pillar; and depositing a second passivation layer over the surface of the first integrated circuit die device, the second passivation layer having openings exposing the plurality of power contact pads and the signal contact pads of the first integrated circuit die.

Example 2. The method of Example 1, further including: forming a hybrid bonding layer on the second passivation layer.

Example 3. The method of Example 2, further including: hybrid bonding the hybrid bonding the first integrated circuit die to a second integrated circuit die to form stacked integrated circuits.

Example 4. The method of Example 3, the stacked integrated circuits span two separate wafers.

Example 5. The method of Example 1, wherein forming the conductive cap above and in electrical contact with two or more of the conductive pillars further includes: contacting two or more conductive pillars arranged in a common column.

Example 6. The method of Example 1, wherein forming the conductive cap above and in electrical contact with two or more of the conductive pillars further includes: contacting two or more conductive pillars arranged in a first column; and contacting two or more conductive pillars arranged in a second column.

Example 7. The method of Example 1, wherein forming the conductive caps further comprises depositing a solder bump on two or more of the conductive pillars.

Example 8. The method of Example 1, wherein removing the first passivation layer further includes wet etching the first passivation layer.

Example 9. The method of Example 1, wherein removing the conductive pillar further includes at least one of chemical mechanical polishing, lapping, grinding, milling, or etching the conductive pillar.

Example 10. The method of Example 1, wherein the surface of the first integrated circuit die has a polished finish after the first passivation layer has been removed.

Example 11. The method of Example 1, wherein the first integrated circuit die conforms to 2 nanometer technology as defined in the 2021 update of the International Roadmap for Devices and Systems published by the Institute of Electrical and Electronics Engineers.

Example 12. An integrated circuit (IC) die including: a die body having functional circuitry formed therein; a plurality of signal terminations disposed on a buried surface of the die body and coupled to the functional circuitry; a plurality of power terminations disposed on the buried surface of the die body and coupled to the functional circuitry; a passivation layer disposed on the buried surface of the die body, the plurality of signal terminations electrically dead ended below the passivation layer; a plurality of probe contact pads disposed on an exposed surface of the passivation layer, the probe contact pads electrically coupled to the plurality of power terminations; and a probing bump disposed exposed surface of the passivation layer, the probing bump in contact with at least two of the plurality of probe contact pads.

Example 13. The IC die of Example 12, wherein probing bump is in contact with three or more of the plurality of probe contact pads.

Example 14. The IC die of Example 12, wherein probing bump is in contact with at least six of the plurality of probe contact pads.

Example 15. The IC die of Example 12, wherein the plurality of probe contact pads in contact with the probing bump are arranged in a common row.

Example 16. The IC die of Example 12, wherein the plurality of probe contact pads in contact with the probing bump are adjacent each other.

Example 17. The IC die of Example 12, wherein conductive pillars disposed through the passivation layer couples the plurality of probe contact pads with the plurality of power terminations.

Example 18. An integrated circuit (IC) device including: a first integrated circuit die comprising a polished surface, the polished surface having a plurality of signal contact pads and power contact pads, the polished surface having a passivation layer and a hybrid bonding layer formed thereon; and a second integrated circuit die including a polished surface, the polished surface of the second integrated circuit die having a plurality of signal contact pads and power contact pads, the polished surface of the second integrated circuit die having a passivation layer and a hybrid bonding layer formed thereon, the hybrid bonding layer of the first integrated circuit die hybrid bonded to the hybrid bonding layer of the second integrated circuit die.

Example 19. The stacked integrated circuit device of Example 18, wherein at least 6 or more of the power contact pads are arranged in a column.

Example 20. The stacked integrated circuit device of Example 19, wherein the first integrated circuit die conforms to 2 nanometer technology as defined in the 2021 update of the International Roadmap for Devices and Systems published by the Institute of Electrical and Electronics Engineers.

Thus, process disclosed herein eliminates the need for large power pads while still enabling wafer sort probing. This new technique allows power pads to be as much as about ten times smaller than conventional power pads, consequently enabling an improved distribution of power pads 2N technology. As such the above described technique avoids displacement of signal pads that are required for hybrid bonds in N2 die stacking. This results in minimal or no disruption to the silicon design on the top RDL layer. And at the same time, allow for sufficient area to interface with conventional probes on probing bumps at wafer sort. After wafer sort, the probing bumps and top passivation layers are removed, allowing growth of hybrid bonds to facilitate AoA die stacking.

While the foregoing is directed to specific examples, other and further examples may be devised without departing from the basic scope thereof, and the scope thereof is determined by the claims that follow.

What is claimed is:

1. A method for fabricating an integrated circuit device, the method comprising:
depositing a first passivation layer over a surface of a first integrated circuit die having a plurality of signal contact pads and a plurality of power contact pads, the first passivation layer masking the plurality of signal contact pads while having openings exposing the plurality of power contact pads;
filling the openings with a conductive material to form a plurality of conductive pillars in electrical contact with the power contact pads;
forming a conductive cap above and in electrical contact with two or more of the conductive pillars;
probing the power contact pads through the conductive cap;
removing the first passivation layer, the conductive cap, and the conductive pillar; and
depositing a second passivation layer over the surface of the first integrated circuit die device, the second passivation layer having openings exposing the plurality of power contact pads and the plurality of signal contact pads of the first integrated circuit die.

2. The method of claim 1, further comprising:
forming a hybrid bonding layer on the second passivation layer.

3. The method of claim 2, further comprising:
hybrid bonding the hybrid bonding layer of the first integrated circuit die to a second integrated circuit die to form stacked integrated circuits.

4. The method of claim 3, the stacked integrated circuits span two separate wafers.

5. The method of claim 1, wherein forming the conductive cap above and in electrical contact with two or more of the conductive pillars further comprises:
contacting two or more conductive pillars arranged in a common column.

6. The method of claim 1, wherein forming the conductive cap above and in electrical contact with two or more of the conductive pillars further comprises:
contacting two or more conductive pillars arranged in a first column; and
contacting two or more conductive pillars arranged in a second column.

7. The method of claim 1, wherein forming the conductive cap further comprises:
depositing a solder bump on two or more of the conductive pillars.

8. The method of claim 1, wherein removing the first passivation layer further comprises wet etching the first passivation layer.

9. The method of claim 1, wherein removing the conductive pillars further comprises at least one of chemical mechanical polishing, lapping, grinding, milling, or etching the conductive pillar.

10. The method of claim 1, wherein the surface of the first integrated circuit die has a polished finish after the first passivation layer has been removed.

11. The method of claim 1, wherein the first integrated circuit die conforms to 2 nanometer technology as defined in the 2021 update of the International Roadmap for Devices and Systems published by the Institute of Electrical and Electronics Engineers.

12. An integrated circuit (IC) die comprising:
a die body having functional circuitry formed therein;
a plurality of signal terminations disposed on a buried surface of the die body and coupled to the functional circuitry;
a plurality of power terminations disposed on the buried surface of the die body and coupled to the functional circuitry;
a passivation layer disposed on the buried surface of the die body, the plurality of signal terminations electrically dead ended below the passivation layer;
a plurality of probe contact pads disposed on an exposed surface of the passivation layer, the probe contact pads electrically coupled to the plurality of power terminations; and
a probing bump disposed on an exposed surface of the passivation layer, the probing bump in contact with at least two of the plurality of probe contact pads.

13. The IC die of claim 12, wherein the probing bump is in contact with three or more of the plurality of probe contact pads.

14. The IC die of claim 12, wherein the probing bump is in contact with at least six of the plurality of probe contact pads.

15. The IC die of claim 12, wherein the plurality of probe contact pads in contact with the probing bump are arranged in a common row.

16. The IC die of claim 12, wherein the plurality of probe contact pads in contact with the probing bump are adjacent each other.

17. The IC die of claim 12, wherein conductive pillars disposed through the passivation layer couples the plurality of probe contact pads with the plurality of power terminations.

18. An integrated circuit (IC) device comprising:
a first integrated circuit die comprising a polished surface, the polished surface having a plurality of signal contact pads and power contact pads, the polished surface having a passivation layer and a hybrid bonding layer formed thereon; and
a second integrated circuit die comprising a polished surface, the polished surface of the second integrated circuit die having a plurality of signal contact pads and power contact pads, the polished surface of the second integrated circuit die having a passivation layer and a hybrid bonding layer formed thereon, the hybrid bonding layer of the first integrated circuit die hybrid bonded to the hybrid bonding layer of the second integrated circuit die.

19. The stacked integrated circuit device of claim 18, wherein at least 6 or more of the power contact pads are arranged in a column.

20. The stacked integrated circuit device of claim 19, wherein the first integrated circuit die conforms to 2 nanometer technology as defined in the 2021 update of the International Roadmap for Devices and Systems published by the Institute of Electrical and Electronics Engineers.
